(19) United States
(12) Patent Application Publication
(10) Pub. No.: US 2012/0189139 A1
(43) Pub. Date: Jul. 26, 2012

(54) Semiconductor Integrated Circuit Having a Switched Charge Pump Unit and Operating Method Thereof

(75) Inventors: Kenichiro Ohara, Kawasaki-shi (JP); Masanori Kumagai, Kawasaki-shi (JP); Kenji Isu, Kawasaki-shi (JP)

(73) Assignee: Renesas Electronics Corporation, Kawasaki-shi (JP)

(21) Appl. No.: 13/353,119

(22) Filed: Jan. 18, 2012

(30) Foreign Application Priority Data
Jan. 24, 2011 (JP) 2011-011716

(51) Int. Cl. H03G 3/00; H03G 3/20; G05F 1/10; H03F 3/04; H03F 3/45

(52) U.S. Cl. 381/107; 330/307; 330/260; 327/536; 330/254

(57) ABSTRACT

Power source noises of a digital amplifier arising from regenerative current of an inductor of a low pass filter is reduced. A semiconductor integrated circuit includes: a digital amplifier, a driver; and a charge pump unit which is supplied with a positive operating voltage and generates a positive power supply voltage and a negative power supply voltage. An output terminal of the digital amplifier is coupled to a low pass filter including an inductor and a filter capacitor. The charge pump unit includes a first switch through a sixth switch, and a first capacitor through a fourth capacitor, all connected via a first node through a sixth node. Regenerative current which flows between the filter capacitor and the positive power supply voltage or the negative power supply voltage is absorbed by the second capacitor, by controlling the sixth switch to an on state.

### CROSS-REFERENCE TO RELATED APPLICATIONS

The disclosure of Japanese Patent Application No. 2011-11716 field on Jan. 24, 2011 including the specification, drawings, and abstract is incorporated herein by reference in its entirety.

### BACKGROUND

The present invention relates to a semiconductor integrated circuit with a built-in digital amplifier which can realize high power efficiency, and an operating method for the same, especially, to technology which is effective in reducing a power source noise of the digital amplifier, arising from regenerative current of an inductor of a low pass filter.

In recent years, especially in the field of audio equipment for portable use operating with a battery, a low power consumption operation is strongly demanded. As an audio amplifier for driving a headphone in this kind of equipment, a Class D amplifier (digital amplifier) has received attention, because of its high power efficiency as compared with an analog amplifier.

Non Patent Literature 1 cited below explains Class A, Class B, Class AB, and Class D of amplifiers.

In a Class A amplifier, output devices are continuously conducting for the entire cycle, and there is always bias current flowing in the output devices. This class has low distortion and high linearity, but at the same time the power efficiency is as low as about 20%. The design of a Class A amplifier is usually not complementary with a high side output device and a low side output device.

A Class B amplifier operates in the opposite way to a Class A amplifier. Output devices only conduct for half the sinusoidal cycle (one conducts in the positive region, and one conducts in the negative region). If there is no input signal supplied, there is no current flowing in the output devices. A Class B amplifier is obviously more efficient than a Class A amplifier, at about 50%, but has some issues with linearity at a crossover point, due to the time required to turn one device off and turn the other device on.

A Class AB amplifier is a combination of a Class A amplifier and a Class B amplifier, and is currently one of the most common types of power amplifier in existence. Both devices are allowed to conduct at the same time, but with just a small amount of current near the crossover point. Since each device is conducting for more than half a cycle but less than the whole cycle, the issue of inherent non-linearity of a Class B amplifier is overcome, without the inefficiency of a Class A amplifier.

A Class D amplifier is in principle a switching amplifier or a PWM amplifier. Here, PWM stands for Pulse Width Modulation. In this type of amplifier, the switches are either fully on or fully off, significantly reducing the power losses in the output devices. Accordingly, efficiencies of 90-95% are possible. The audio input signal is used to modulate a PWM carrier signal which drives the output devices, and the final stage is a low pass filter to remove the PWM carrier frequency at a high frequency.

FIG. 1 of Non Patent Literature 1 cited below described a half bridge Class D amplifier which is configured with an error amplifier, a triangular-wave generator, a comparator, a dead time gate driver, a level shift circuit, two N-channel MOS transistors, a feedback circuit, and a low pass filter. An audio input signal is supplied to an inverting input terminal of the error amplifier and a ground potential GND is supplied to a noninverting input terminal. An output signal of the error amplifier is supplied to one input terminal of the comparator. A triangular-wave signal generated by the triangular-wave generator is supplied to the other input terminal of the comparator. An output signal of the comparator is supplied to an input terminal of the dead time gate driver. One output signal of the dead time gate driver is supplied to a gate terminal of an N-channel MOS transistor as a high side output device via the level shift circuit. The other output signal of the dead time gate driver is supplied to a gate terminal of an N-channel MOS transistor as a low side output device. A positive power supply voltage is supplied to a source terminal of the N-channel MOS transistor as the high side output device, and a negative power supply voltage is supplied to a source terminal of the N-channel MOS transistor as the low side output device. Drain terminals of both transistors are coupled in common to one end of an inductor of the low pass filter. The other end of the inductor is coupled to one end of a filter capacitor of the low pass filter, and one end of a speaker load. The other end of the capacitor of the low pass filter and the other end of the speaker load are coupled to the ground potential GND. One end of the inductor of the low pass filter is coupled to the inverting input terminal of the error amplifier via the feedback circuit. For example, in response to increase in the signal level of the audio input signal, a high level period (high level pulse width) of a pulse of the output signal of the comparator increases. In response to the pulse signal of the output signal of the comparator, the dead time gate driver generates a high side output device driving signal and a low side output device driving signal, which are of opposite phase with each other. Since the high side output device driving signal and the low side output device driving signal of opposite phase change in level after passing a dead time at a low level at the same time, the high side output device and the low side output device are prevented from turning on at the same time, avoiding large current flowing through both devices.

The Class D amplifier described in Non Patent Literature 1 cited below is also called a digital amplifier or a one-bit amplifier. As a Class D amplifier, an amplifier which uses pulse density modulation (PDM) in place of pulse width modulation (PWM) is also known.

On the other hand, although it is not described by Non Patent Literature 1 cited below, a Class C amplifier is also known. The Class C amplifier performs an operation similar to the switching operation in which a bias deeper than a cutoff threshold value is supplied to an amplification device and an output signal is obtained only when an input signal with large amplitude is supplied. Although many harmonic components are included in an output signal, the Class C amplifier removes the harmonic components by coupling a filter circuit to the output, and is used as a narrow-band high-frequency amplifier of large electric power and of high efficiency

In order to solve an issue that, in a feedback digital amplifier to which a PWM signal is input, a digital processing electronic volume is influenced by quantization error which is peculiar to the digital signal processing in a small-signal area, Patent Literature 1 cited below discloses a technology in which an electronic volume device is coupled between an output terminal of a digital signal processing unit and an input terminal of a feedback digital amplifier, with the configuration to control the amplitude of a PWM signal wave responding to a digital control signal of plural bits. Since this electronic volume device can control directly the signal amplitude voltage of a PWM signal wave in analog in response to a digital control signal, it is postulated that the volume characteristic which corresponds to an analog processing electronic volume is realized.

### PATENT LITERATURE

(Patent Literature 1) Japanese Patent Laid-open No. 2010-87939

### NON PATENT LITERATURE

(Non Patent Literature 1) International Rectifier Application Note AN-1071 “Class D Audio Amplifier Basics”, by Jun Honda & Jonathan Adams, PP. 1-14, http://www.irf.com/technical-info/appnotes/an-1071.pdf (searched on Nov. 18, 2010)

The present inventors have been engaged in development of an audio system LSI (large-scale semiconductor integrated circuit) with a built-in digital amplifier, in advance of the present invention.

In the development, the present inventors discovered the issue of power supply pumping inherent in a digital amplifier (Class D amplifier). It is conjectured that the power supply pumping originates in regenerative current flowing into an inductor of a low pass filter which is provided for removing the PWM carrier frequency component of a high frequency in the final stage of a digital amplifier.

In the period when a low side output device is in an on state, energization current flows from one end of a capacitor of the low pass filter, and one end of a speaker load toward a negative power supply voltage via the inductor of the low pass filter. In the period when the low side output device changes from an on state to an off state and the high side output device changes from an off state to an on state, regenerative current of the same current value and the same direction as the energization current described above flows from the one end of the capacitor of the low pass filter and the one end of the speaker load toward a positive power supply voltage via the inductor and the high side output device. Therefore, the positive power supply voltage is varied by inflow of the regenerative current to the positive power supply voltage.

In the period when the high side output device is in an on state, energization current flows from the positive power supply voltage toward the one end of the capacitor of the low pass filter and the one end of the speaker load via the inductor of the low pass filter. In the period when the high side output device changes from an on state to an off state, and the low side output device changes from an off state to an on state, regenerative current of the same current value and the same direction as the energization current described above flows from the negative power supply voltage toward the one end of the capacitor of the low pass filter and the one end of the speaker load via the low side output device and the inductor. Therefore, the negative power supply voltage is varied by inflow of the regenerative current to the negative power supply voltage.

The issue of power supply pumping arising from inflow to the power supply of the energy stored in an inductor of an output LPF is also described at page 12 of Non Patent Literature 1. It is also described in page 12 that, since the power supply in general cannot absorb the energy which returns from a load, the power supply voltage rises and varies as the result. It is further described in page 12 that the power supply pumping is not generated by adoption of a full bridge system because the energy kicked back to the power supply voltage from one side of the switching device is absorbed by the other side of the switching device. However, the examination of the present inventors prior to the present invention has also clarified the issue that the full bridge system requires two digital amplifiers and two inductors of the low pass filter with increase in the circuit scale.

It has been also clarified that the power supply pumping of the digital amplifier built in the semiconductor integrated circuit not only causes a malfunction of an electronic volume and internal circuits such as a ΔΣ modulator and PWM generator, which are included in a digital signal processing unit built in the semiconductor integrated circuit as well, but also produces a disturbance in the audio reproduction of a low frequency region of several tens or less Hz.

In advance of the present invention, the present inventors examined how to suppress the power supply pumping by coupling a capacitor between the positive power supply voltage and the negative power supply voltage of the digital amplifier. However, it became clear that, in order to obtain a sufficient suppression quantity of the power supply pumping, it is necessary to employ a capacitor with a very large value of capacitance of 470 μF. However, employment of a capacitor with a very large value of capacitance may cause an issue of increase in the cost and mounting area of a wiring substrate of an audio equipment for portable use. This issue has been clarified by the examination of the present inventors performed prior to the present invention.

In the above-described development, the present inventors have examined the electronic volume device disclosed by Patent Literature 1.

Since the electronic volume device disclosed by Patent Literature 1 is coupled between an output terminal of the digital signal processing unit and an input terminal of the feedback digital amplifier, the noise generated in the ΔΣ modulator and the PWM generator of the digital signal processing unit in the preceding stage of the electronic volume device can be decreased according to the attenuation in the electronic volume device. However, it has been clarified by the examination of the present inventors performed prior to the present invention that noises such as power supply pumping generated in the feedback digital amplifier in the latter stage of the electronic volume device can not be reduced by the electronic volume device.

When a digital amplifier gain control circuit is arranged to the electronic volume device disclosed by Patent Literature 1 for the purpose of reduction of the noise generated in the feedback digital amplifier, a pop noise (popping sound) originating in a rapid change of an audio signal in response to the change of the digital control signal is generated, because the signal amplitude of the PWM signal wave is controlled in response to a plural-bit digital control signal. The present issue has been also clarified by the examination of the present inventors performed prior to the present invention.

### SUMMARY

The present invention has been made as the result of the above-described examinations performed by the present inventors prior to the present invention.

Therefore, the present invention has been made in view of the above circumstances and intends to reduce the power source noise of the digital amplifier arising from regenerative current of an inductor of a low pass filter.

The present invention also intends to reduce the pop noise of the electronic volume provided in the digital amplifier.

The above and other purposes and new features will become clear from description of the specification and the accompanying drawings of the present invention.

The following explains briefly typical embodiments disclosed by the present application.

That is, a typical embodiment of the present invention is a semiconductor integrated circuit which includes a digital amplifier (30) which includes a high side output device (31), a low side output device (32), and a driver (33); and a charge pump unit (50) which is able to generate a positive power supply voltage (+Vcc) and a negative power supply voltage (−Vcc), to be supplied to the digital amplifier, by being supplied with a positive operating voltage (Vop).

The driver of the digital amplifier operates with the positive power supply voltage and the negative power supply voltage, a first output terminal and a second output terminal of the driver are coupled to a control input terminal of the high side output device and a control input terminal of the low side output device, respectively. An output current path of the high side output device is coupled between the positive power supply voltage and an output terminal of the digital amplifier, and, an output current path of the low side output device is coupled between the output terminal of the digital amplifier and the negative power supply voltage.

The output terminal of the digital amplifier is coupled to a low pass filter (LPF) including an inductor (36) and a filter capacitor (37).

The charge pump unit includes a first switch (SW1) through a fifth switch (SW5), and a first capacitor (C1) through a fourth capacitor (C4), all connected via a first node (191) to a sixth node (196).

The positive operating voltage (Vop) is supplied to one end of the first capacitor (C1) via the first switch (SW1), a ground potential (GND) is supplied to one end of the second capacitor (C2) via the second switch (SW2), and the other end of the first capacitor (C1) and the other end of the second capacitor (C2) are coupled to a second node (192).

The one end of the first capacitor (C1) is coupled to one end of the third capacitor (C3) via the third switch (SW3), and the one end of the second capacitor (C2) is coupled to one end of the fourth capacitor (C4) via the fourth switch (SW4). A fifth node (195), which is connected to the other end of the third capacitor (C3) and the other end of the fourth capacitor (C4), is coupled to the ground potential (GND), and the second node (192) is coupled to the fifth node (195) via the fifth switch (SW5).

The positive power supply voltage (+Vcc) is generated from the one end of the third capacitor (C3), and the negative power supply voltage (−Vcc) is generated from the one end of the fourth capacitor (C4).

The charge pump unit includes further a sixth switch (SW6) coupled between the one end of the third capacitor (C3) at the fourth node (194) and the second node (192).

The regenerative current flows between the filter capacitor (37) of the low pass filter (LPF) and the positive power supply voltage (+Vcc) or the negative power supply voltage (−Vcc), via the inductor (36) and the high side output device in an on state or the low side output device in an on state. This regenerative current is absorbed by the second capacitor (C2), by controlling the sixth switch (SW6) of the charge pump unit to an on state (refer to FIG. 4).

The following explains briefly an effect obtained by the typical inventions to be disclosed in the present application.

That is, according to the present invention, it is possible to reduce the power source noise of the digital amplifier arising from the regenerative current of the inductor of the low pass filter.

### BRIEF DESCRIPTION OF THE DRAWINGS

FIG. 1 is a drawing illustrating a configuration of a semiconductor integrated circuit 100 with a built-in digital amplifier according to Embodiment 1 of the present invention;

FIG. 2 is a drawing explaining operation of a charge cycle of a first capacitor C1 and a second capacitor C2 on the input side of a charge pump unit 50 included in the semiconductor integrated circuit 100 with the built-in digital amplifier according to Embodiment 1 of the present invention, illustrated in FIG. 1;

FIG. 3 is a drawing explaining operation of a charge cycle of a third capacitor C3 and a fourth capacitor C4 on the output side of the charge pump unit 50 included in the semiconductor integrated circuit 100 with the built-in digital amplifier according to Embodiment 1 of the present invention, illustrated in FIG. 1;

FIG. 4 is a drawing explaining operation of the charge pump unit 50, a digital amplifier 30, and a low pass filter LPF, included in the semiconductor integrated circuit 100 with the built-in digital amplifier according to Embodiment 1 of the present invention, illustrated in FIG. 1;

FIG. 5 is a drawing illustrating a waveform of a PWM digital audio amplified output signal Vout at an output terminal of the digital amplifier 30 and a waveform of an analog audio amplified output signal Vsp at an output terminal of the low pass filter LPF, wherein the output terminal 300 of the digital amplifier 30 is a common node of a drain terminal of a high side output device 31 and a drain terminal of a low side output device 32 of the digital amplifier 30 included in the semiconductor integrated circuit 100 with the built-in digital amplifier according to Embodiment 1 of the present invention, illustrated in FIG. 1;

FIG. 6 is a drawing illustrating the state of analog amplitude control of a PWM digital audio signal B by a PWM amplitude control electronic volume 22, and the state of amplitude control of a PWM digital audio amplified signal E by a digital amplifier gain control circuit 23, provided in an electronic volume unit 20 included in the semiconductor integrated circuit 100 with the built-in digital amplifier according to Embodiment 1 of the present invention, illustrated in FIG. 1;

FIG. 7 is a drawing illustrating a manner in which popping sound is reduced by use of the electronic volume unit 20 of the semiconductor integrated circuit 100 with the built-in digital amplifier according to Embodiment 1 of the present invention, illustrated in FIG. 1;

FIG. 8 is a drawing explaining operation of the charge pump unit 50, the digital amplifier 30, and the low pass filter LPF, included in the semiconductor integrated circuit 100 with the built-in digital amplifier according to Embodiment 1 of the present invention, illustrated in FIG. 1, when the state where a low level period of the duty of the output of the digital amplifier 30 is longer than a high level period continues for a long period of time; and

FIG. 9 is a drawing explaining operation of the charge pump unit 50, the digital amplifier 30, and the low pass filter LPF, included in the semiconductor integrated circuit 100 with the built-in digital amplifier according to Embodiment 1 of the present invention, illustrated in FIG. 1, when the state where a high level period of the duty of the output of the digital amplifier 30 is longer than a low level period continues for a long period of time.

### DETAILED DESCRIPTION

### 1. Outline of Embodiment

First, an outline of a typical embodiment of the invention disclosed in the present application is explained. A numerical symbol of the drawing referred to in parentheses in the outline explanation about the typical embodiment only illustrates what is included in the concept of the component to which the numerical symbol is attached.

(1) A typical embodiment of the present invention is a semiconductor integrated circuit which includes a digital amplifier (30) which includes a high side output device (31), a low side output device (32), and a driver (33); and a charge pump unit (50) which is able to generate a positive power supply voltage (+Vcc) and a negative power supply voltage (−Vcc), to be supplied to the digital amplifier, by being supplied with a positive operating voltage (Vop).

The driver of the digital amplifier operates with the positive power supply voltage and the negative power supply voltage, and a first output terminal and a second output terminal of the driver are coupled to a control input terminal of the high side output device and a control input terminal of the low side output device, respectively. An output current path of the high side output device is coupled between the positive power supply voltage and an output terminal (300) of the digital amplifier, and, an output current path of the low side output device is coupled between the output terminal of the digital amplifier and the negative power supply voltage.

The output terminal (300) of the digital amplifier is coupled to a low pass filter (LPF) including an inductor (36) and a filter capacitor (37).

The charge pump unit includes a first switch (SW1) through a fifth switch (SW5), and a first capacitor (C1) through a fourth capacitor (C4), all connected via a first node (191) through a sixth node (196).

The positive operating voltage (Vop) is supplied to one end of the first capacitor (C1) via the first switch (SW1), a ground potential (GND) is supplied to one end of the second capacitor (C2) via the second switch (SW2), and the other end of the first capacitor (C1) and the other end of the second capacitor (C2) are coupled to a second node (192).

The one end of the first capacitor (C1) is coupled to one end of the third capacitor (C3) via the third switch (SW3), and the one end of the second capacitor (C2) is coupled to one end of the fourth capacitor (C4) via the fourth switch (SW4). A fifth node (195), which is connected to the other end of the third capacitor (C3) and the other end of the fourth capacitor (C4), is coupled to the ground potential (GND). The second node (192) is coupled to the fifth node (195) via the fifth switch (SW5).

The positive power supply voltage (+Vcc) is generated from the one end of the third capacitor (C3), and the negative power supply voltage (−Vcc) is generated from the one end of the fourth capacitor (C4).

The charge pump unit includes further a sixth switch (SW6) coupled between the one end of the third capacitor (C3) and the second node (192).

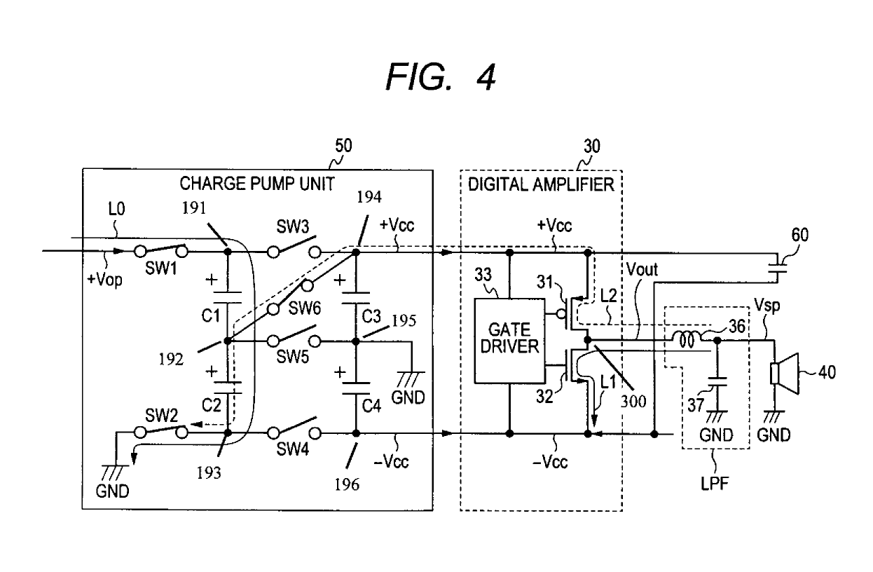

The regenerative current flows between the filter capacitor (37) of the low pass filter (LPF) and the positive power supply voltage (+Vcc) or the negative power supply voltage (−Vcc), via the inductor (36) and the high side output device in an on state or the low side output device in an on state. This regenerative current is absorbed by the second capacitor (C2), by controlling the sixth switch (SW6) of the charge pump unit to an on state (refer to FIG. 4).

In the charge pump unit 50, the topology of the capacitors (C1)-(C4) and switches (SW1)-(SW6) is defined by a plurality of nodes (191)-(196). First capacitor (C1) is connected between a first node (191) and a second node (192). Second capacitor (C2) is connected between the second node (192) and a third node (193). Third capacitor (C3) is connected between a fourth node (194) and a fifth node (195). Fourth capacitor is connected between the fifth node (195) and a sixth node (196).

First switch (SW1) selectively connects the operating voltage (+Vop) to the first node (191) while second switch (SW2) selectively connects the ground potential (GND) to the third node (193). Third switch (SW3) selectively connects the first node (191) and the fourth node (194). Fourth switch (SW4) selectively connects the third node (193) and the sixth node (196). Fifth switch (SW5) selectively connects the second node (192) and the fifth node (195). Sixth switch (SW6) selectively connects the second node (192) and the fourth node (194).

Finally, the positive power supply voltage (+Vcc) is connected to the fourth node (194), the negative power supply voltage (−Vcc) is connected to the sixth node (194), with the fifth node (195) being connected to the ground potential (GND).

According to the embodiment, it is possible to reduce the power source noise of the digital amplifier arising from the regenerative current of the inductor of the low pass filter.

In one embodiment, the charge pump unit repeats operation of a charge cycle of an input side capacitor and operation of a charge cycle of an output side capacitor, in response to a level change of a charge pump driving clock signal.

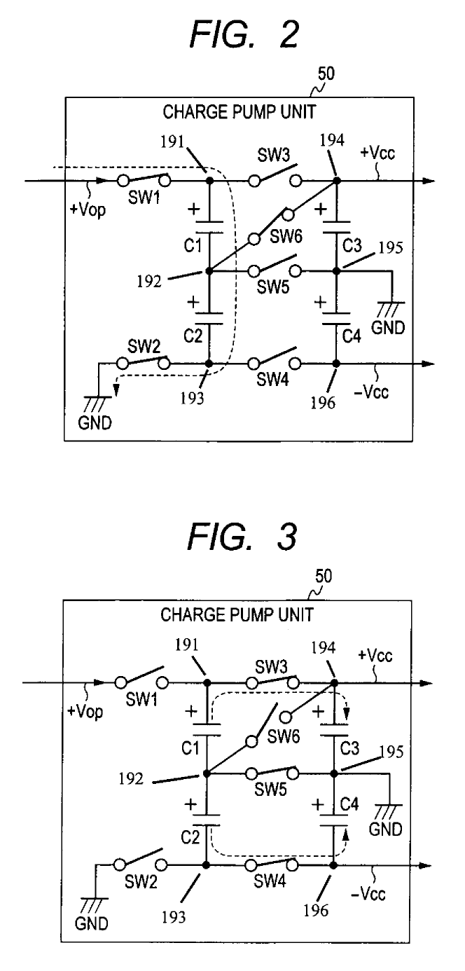

In the charge cycle of the input side capacitor, by controlling the first switch (SW1), the second switch (SW2), and the sixth switch (SW6) to an on state, and controlling the third switch (SW3), the fourth switch (SW4), and the fifth switch (SW5) to an off state, the positive operating voltage (Vop) is supplied to the one end of the first capacitor (C1), and the ground potential (GND) is supplied to the one end of the second capacitor (C2) (refer to FIG. 2).

In the charge cycle of the output side capacitor, by controlling the first switch (SW1), the second switch (SW2), and the sixth switch (SW6) to an off state, and controlling the third switch (SW3), the fourth switch (SW4), and the fifth switch (SW5) to an on state, the positive power supply voltage (+Vcc) is generated from the one end of the third capacitor (C3), and the negative power supply voltage (−Vcc) is generated from the one end of the fourth capacitor (C4) (refer to FIG. 3).

In one embodiment, in a charge cycle of the input side capacitor, the high side output device and the low side output device of the digital amplifier are controlled to an on state and an off state, respectively, by the first driving signal of the first output terminal of the driver and the second driving signal of the second output terminal.

In a charge cycle of the output side capacitor, the high side output device and the low side output device of the digital amplifier are controlled to an off state and an on state, respectively, by the first driving signal of the first output terminal of the driver and the second driving signal of the second output terminal.

In one embodiment, the digital amplifier includes further a differential amplifier (34), a closed-loop characteristics setting circuit (35), and a negative feedback resistor (R_{FB}).

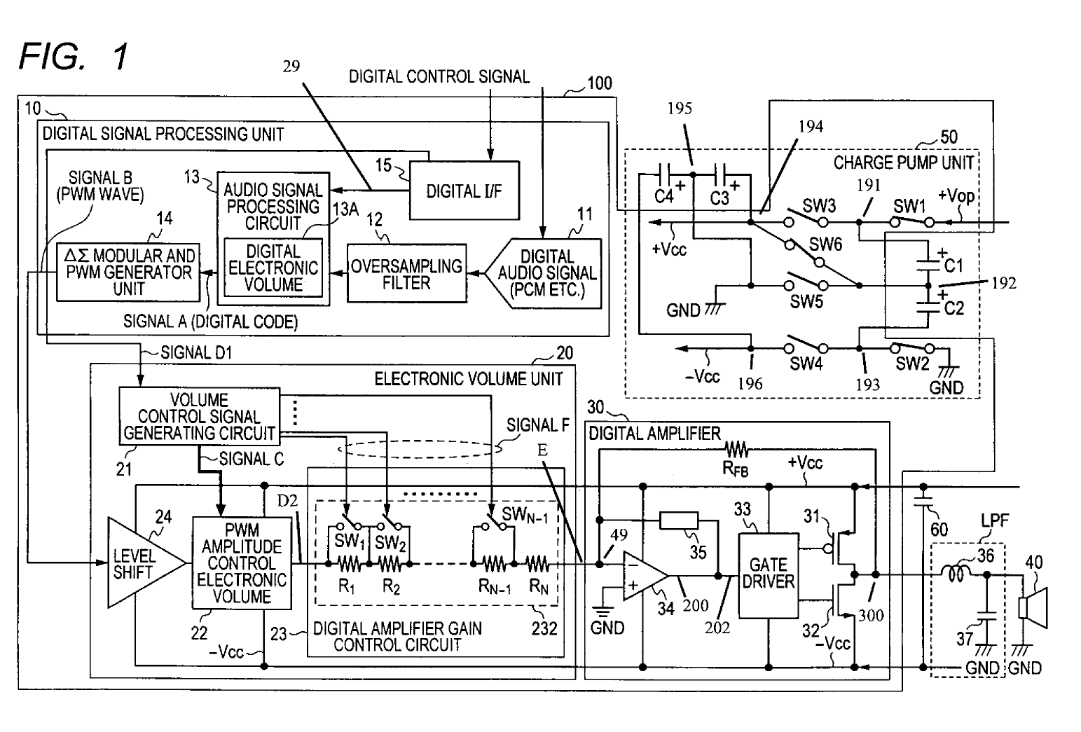

A non-inverting input terminal (+) of the differential amplifier is coupled to the ground potential (GND), the closed-loop characteristics setting circuit (35) is coupled between an inverting input terminal (−) (49) and an output terminal (200) of the differential amplifier (34), the output terminal (200) of the differential amplifier is coupled to an input terminal (202) of the driver, and the negative feedback resistor (R_{FB}) is coupled between the inverting input terminal (−) (49) of the differential amplifier and the output terminal (200) of the digital amplifier (refer to FIG. 1).

In one embodiment, the semiconductor integrated circuit further includes an electronic volume unit (20) including a volume control signal generating circuit (21), an amplitude control electronic volume (22), and a digital amplifier gain control circuit (23).

In response to a digital control signal (D1), the volume control signal generating circuit (21) generates an amplitude control digital signal (C) to be supplied to the amplitude control electronic volume (22) and a gain control digital signal (F) to be supplied to the digital amplifier gain control circuit (23).

The amplitude control electronic volume (22), operating with the positive power supply voltage (+Vcc) and the negative power supply voltage (−Vcc), controls analog amplitude of a digital audio output signal (D2) supplied from an output of the amplitude control electronic volume (22) to an input of the digital amplifier gain control circuit (23), in response to the amplitude control digital signal (C).

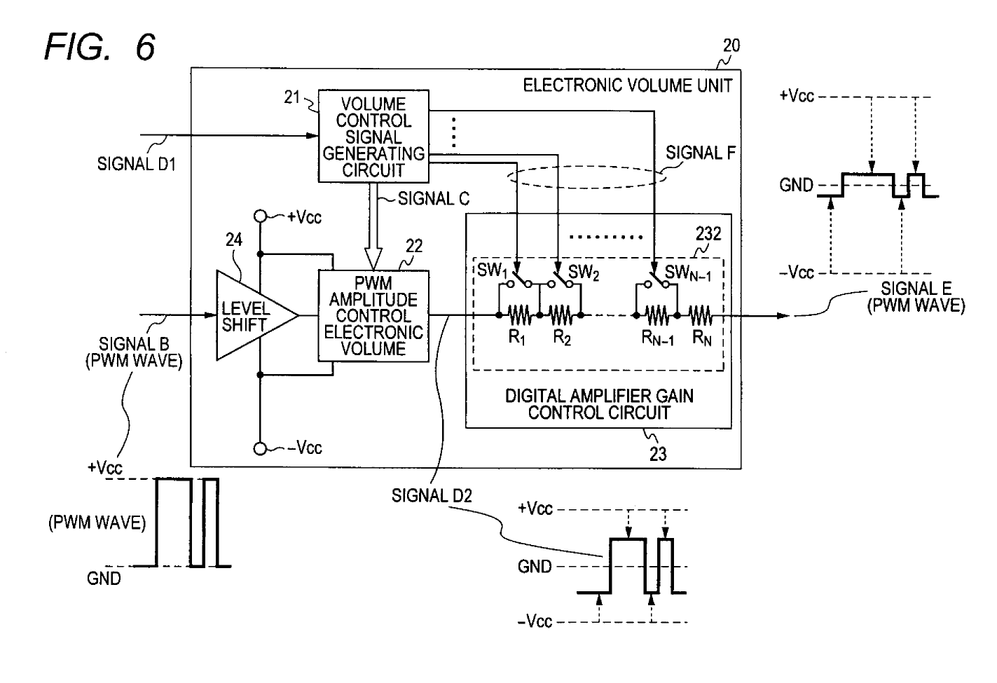

The digital amplifier gain control circuit (23) controls amplitude of a digital audio amplified output signal of the output terminal of the digital amplifier by controlling the voltage gain (R_{FB}/R_{ATT}) of the digital amplifier in response to the gain control digital signal (F) (refer to FIG. 1 and FIG. 6).

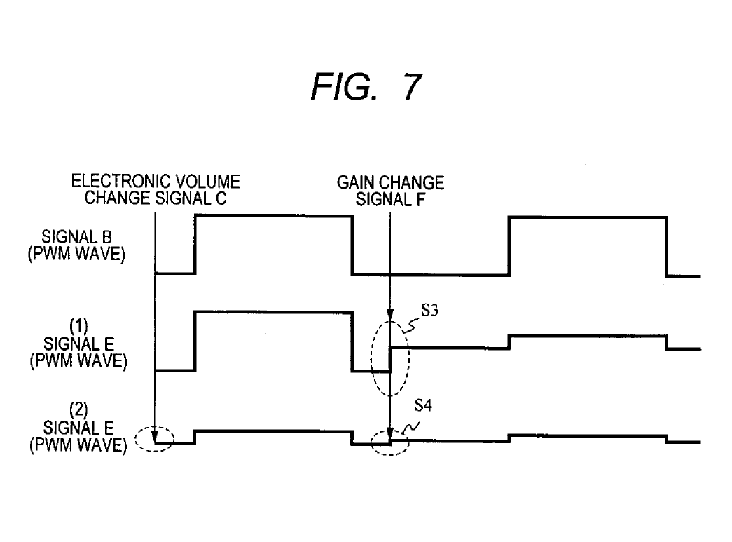

In one, the timing of controlling the analog amplitude of the digital audio output signal by the amplitude control electronic volume (22) in response to the amplitude control digital signal (C) precedes in time the timing of controlling the digital audio amplified output signal (E) by the digital amplifier gain control circuit (23) in response to the gain control digital signal (F) (refer to FIG. 1, FIG. 6, and FIG. 7).

In one embodiment, the timing of supplying the amplitude control digital signal (C) from the volume control signal generating circuit (21) to the amplitude control electronic volume (22) is advanced, on the other hand, the timing of supplying the gain control digital signal (F) from the volume control signal generating circuit (21) to the digital amplifier gain control circuit (23) is delayed.

In one, the digital amplifier gain control circuit (23) includes a variable attenuator (232) including plural resistors (R₁, R₂, - - - , R_{N-1}, and R_{N}) coupled in series and plural bypass switches (SW₁, SW₂, - - - , SW_{N-1}, and SW_{N}) coupled in series with each bypass switch connected in parallel across a corresponding resistor, in order to control the voltage gain (R_{FB}/R_{ATT}) of the digital amplifier in response to the gain control digital signal (F).

The on/off state of the plural bypass switches (SW₁, SW₂, - - - , SW_{N-1}, and SW_{N}) of the variable attenuator (232) is controlled by the gain control digital signal (F) supplied from the volume control signal generating circuit (21) (refer to FIG. 1, FIG. 6, and FIG. 7).

In a further yet another more preferred embodiment, the semiconductor integrated circuit further includes an audio signal processing circuit (13) with a built-in digital electronic volume (13A), a ΔΣ modulator-PWM/PDM generator unit (14), and a digital signal processing unit (10) including a digital interface unit (15).

The digital interface unit (15) of the digital signal processing unit (10) generates the digital control signal (D1) to be supplied to the volume control signal generating circuit (21) of the electronic volume unit (20).

The digital electronic volume (13A) of the audio signal processing circuit (13) controls a digital amplitude value of a digital audio signal, in response to a digital volume control signal (29) supplied from the digital interface unit (15).

The ΔΣ modulator-PWM/PDM generator unit (14) generates a PWM/PDM digital audio signal (B) in response to the digital audio signal supplied from the output terminal of the audio signal processing circuit (13) (refer to FIG. 1).

In a specific embodiment, the high side output device (31) and the low side output device (32) included in the digital amplifier (30) are MOS transistors integrated in the semiconductor integrated circuit (100).

(2) A typical embodiment of another viewpoint of the present invention is an operating method of a semiconductor integrated circuit comprised of a digital amplifier (30) which includes a high side output device (31), a low side output device (32), and a driver (33); and a charge pump unit (50) which is able to generate a positive power supply voltage (+Vcc) and a negative power supply voltage (−Vcc), to be supplied to the digital amplifier, in response to a positive operating voltage (Vop).

The driver (33) of the digital amplifier (30) operates with the positive power supply voltage (+Vcc) and the negative power supply voltage (−Vcc), and a first output terminal and a second output terminal of the driver (33) are coupled to a control input terminal of the high side output device and a control input terminal of the low side output device, respectively. An output current path of the high side output device is coupled between the positive power supply voltage (+Vcc) and an output terminal (300) of the digital amplifier (30), and an output current path of the low side output device is coupled between the output terminal (300) of the digital amplifier (30) and the negative power supply voltage (−Vcc).

The output terminal (300) of the digital amplifier (30) is coupled to a low pass filter (LPF) including an inductor (36) and a filter capacitor (37).

The charge pump unit includes a first switch (SW1) through a fifth switch (SW5), and a first capacitor (C1) through a fourth capacitor (C4), all connected via a first node (191) through a sixth node (196).

The positive operating voltage (Vop) is supplied to one end of the first capacitor (C1) via the first switch (SW1), a ground potential (GND) is supplied to one end of the second capacitor (C2) via the second switch (SW2), and the other end of the first capacitor (C1) and the other end of the second capacitor (C2) are coupled to a second node (192).

The one end of the first capacitor (C1) is coupled to one end of the third capacitor (C3) via the third switch (SW3), and the one end of the second capacitor (C2) is coupled to one end of the fourth capacitor (C4) via the fourth switch (SW4). A second node (195), which is connected to the other end of the third capacitor (C3) and the other end of the fourth capacitor (C4), is coupled to the ground potential (GND). The second node (192) is coupled to the fifth node (195) via the fifth switch (SW5).

The positive power supply voltage (+Vcc) is generated from the one end of the third capacitor (C3), and the negative power supply voltage (−Vcc) is generated from the one end of the fourth capacitor (C4).

The charge pump unit includes further a sixth switch (SW6) coupled between the one end of the third capacitor (C3) and the second node (192).

The regenerative current flows between the filter capacitor (37) of the low pass filter (LPF) and the positive power supply voltage (+Vcc) or the negative power supply voltage (−Vcc), via the inductor (36) and the high side output device in an on state or the low side output device in an on state. This regenerative current is absorbed by the second capacitor (C2), by controlling the sixth switch (SW6) of the charge pump unit to an on state (refer to FIG. 4).

According to the embodiment, it is possible to reduce the power source noise of the digital amplifier arising from the regenerative current of the inductor of the low pass filter.

### 2. Details of Embodiment

Next, the embodiment is explained in further detail. In the entire diagrams for explaining the embodiments of the present invention, the same symbol is attached to a component which has the same function, and the repeated explanation thereof is omitted.

### Embodiment 1

A configuration of a semiconductor integrated circuit with a built-in digital amplifier

FIG. 1 illustrates a configuration of a semiconductor integrated circuit 100 with a built-in digital amplifier according to Embodiment 1 of the present invention.

As illustrated in FIG. 1, the semiconductor integrated circuit 100 includes a digital signal processing unit 10, an electronic volume unit 20, a digital amplifier 30, and a charge pump unit 50, which are integrated in a semiconductor chip.

The digital signal processing unit 10 has a function to execute digital signal processing of a PCM digital audio signal transferred from a digital signal supply unit (not shown in FIG. 1). Here, PCM stands for pulse code modulation. Accordingly, a PCM digital audio signal 11 is supplied to the digital signal processing unit 10.

The Digital Signal Processing Unit

The digital signal processing unit 10 illustrated in FIG. 1 includes further an oversampling filter 12, an audio signal processing circuit 13 with a built-in digital electronic volume 13A, a ΔΣ modulator-PWM generator unit 14, and a digital interface unit 15. The digital interface unit 15 has a function to supply a digital control signal from a microcomputer etc. of portable-use audio equipment in which the semiconductor integrated circuit 100 is mounted, to the audio signal processing circuit 13 and the electronic volume unit 20.

The audio signal processing circuit 13 has a function to perform signal processing of a PCM digital audio signal supplied from the oversampling filter 12, in response to the digital control signal supplied from the digital interface unit 15. Especially, the digital electronic volume 13A of the audio signal processing circuit 13 executes volume control by controlling a digital amplitude value of the PCM digital audio signal 11 in response to a first digital volume control signal 29 from the digital interface unit 15. In this way, a digital audio signal A is generated from an output terminal of the audio signal processing circuit 13.

The ΔΣ modulator-PWM generator unit 14 generates a PWM digital audio signal B in response to the digital audio signal A supplied from the output terminal of the audio signal processing circuit 13.

The Electronic Volume Unit

The electronic volume unit 20 includes a volume control signal generating circuit 21, a level shift circuit 24, a PWM amplitude control electronic volume 22, and a digital amplifier gain control circuit 23.

The volume control signal generating circuit 21 generates a PWM amplitude control digital signal C to be supplied to the PWM amplitude control electronic volume 22, and a gain control digital signal F to be supplied to the digital amplifier gain control circuit 23, in response to a digital control signal D1 supplied from the digital interface unit 15.

The level shift circuit 24, operating with the positive power supply voltage +Vcc and the negative power supply voltage −Vcc, generated by the charge pump unit 50, converts analog amplitude of the PWM digital audio signal B supplied from the ΔΣ modulator-PWM generator unit 14, centering on a positive voltage and changing between the ground potential GND and the positive power supply voltage +Vcc, into a PWM digital audio signal, centering on the ground potential GND and changing between the negative power supply voltage −Vcc and the positive power supply voltage +Vcc.

The PWM amplitude control electronic volume 22, operating with the positive power supply voltage +Vcc and the negative power supply voltage −Vcc, generated by the charge pump unit 50, controls analog amplitude of the digital audio signal supplied from level shift circuit 24, centering on the ground potential GND and changing between the negative power supply voltage −Vcc and the positive power supply voltage +Vcc, in response to the PWM amplitude control digital signal C supplied from the volume control signal generating circuit 21.

The timing of controlling the analog amplitude of the PWM digital audio signal by the PWM amplitude control electronic volume 22 in response to the PWM amplitude control digital signal C precedes in time the timing of controlling the voltage amplitude of the PWM digital audio amplified signal E with the use of the digital amplifier gain control circuit 23 responding a gain control digital signal F as explained in the following. This timing adjustment becomes realizable by advancing the timing of supplying the PWM amplitude control digital signal C from the volume control signal generating circuit 21 to the PWM amplitude control electronic volume 22 and delaying the timing of supplying the gain control digital signal F from the volume control signal generating circuit 21 to the digital amplifier gain control circuit 23.

The digital amplifier gain control circuit 23 includes a variable attenuator 232 in order to process the PWM digital audio signal D2 supplied from the PWM amplitude control electronic volume 22. The variable attenuator 232 includes plural resistors R₁, R₂, - - - , R_{N-1}, and R_{N} coupled in series and plural bypass switches SW₁, SW₂, - - - , SW_{N-1}, and SW_{N} coupled in series. Each resistor and each bypass switch are coupled in parallel. The on/off state of each of the plural bypass switches SW₁, SW₂, - - - , SW_{N-1}, and SW_{N} of the variable attenuator 232 is controlled by the gain control digital signal F supplied from the volume control signal generating circuit 21. When all plural bypass switches SW₁, SW₂, - - - , SW_{N-1}, and SW_{N} of the variable attenuator 232 are controlled to an on state, the value of resistance of the variable attenuator 232 is minimized, and the voltage amplitude of the PWM digital audio amplified signal E of the digital amplifier 30, applied to the inverting input terminal (−) (49) of the differential amplifier 34, and connected to the driver output 300 via the negative feedback resistor R_{FB}, is at a maximum. It is also possible to configure the variable attenuator 232 with plural resistors coupled in parallel, each having a different value of resistance, and with plural series switches each coupled to each of the plural resistors in series, thereby allowing to select a resistor to use by the plural series switches.

The Digital Amplifier

The digital amplifier 30, operating by the positive power supply voltage +Vcc and the negative power supply voltage −Vcc supplied by the charge pump unit 50, amplifies the PWM digital audio signal E supplied from the digital amplifier gain control circuit 23. This digital amplifier 30 includes a P-channel MOS transistor of a high side output device 31, an N-channel MOS transistor of a low side output device 32, a gate driver 33, a differential amplifier 34, and a closed-loop characteristics setting circuit 35. The voltage gain of the digital amplifier 30 is determined by a ratio of a variable resistance R_{ATT} of a variable attenuator 232 of the digital amplifier gain control circuit 23 to a negative feedback resistor R_{FB}; namely by the ratio −R_{FB}/R_{ATT}.

An inverting input terminal 49 and a non-inverting input terminal of the differential amplifier 34 are coupled to an output terminal of the digital amplifier gain control circuit 23 and the ground potential GND, respectively. An output terminal 200 of the differential amplifier 34 is coupled to an input terminal 202 of the gate driver 33. A first output terminal and a second output terminal of the gate driver 33 are coupled to a gate terminal of the high side output device 31 and a gate terminal of the low side output device 32, respectively. The closed-loop characteristics setting circuit 35 is coupled between the noninverting input terminal 49 and the output terminal 200 of the differential amplifier 34. A source terminal of the high side output device 31 and a source terminal of the low side output device 32 are coupled to the positive power supply voltage +Vcc and the negative power supply voltage −Vcc, respectively. A drain terminal of the high side output device 31 and a drain terminal of the low side output device 32 are connected to a common drain node 300 formed the driver's output terminal 300, which in turn, is coupled to an input terminal of the low pass filter LPF. The negative feedback resistor R_{FB} is coupled between the common drain node 300 of the drain terminal of the high side output device 31 and the drain terminal of the low side output device 32, and the inverting input terminal 49 of the differential amplifier 34. In order to suppress the PWM carrier frequency of a high frequency of the output of the digital amplifier 30, the low pass filter LPF includes an inductor 36 and a filter capacitor 37. One end of the inductor 36 is coupled to the common drain node 300 of the drain terminal of the high side output device 31 and the drain terminal of the low side output device 32. The other end of the inductor 36 is coupled to one end of the filter capacitor 37 and one end of a load 40, such as a headphone and a speaker, while the other end of the filter capacitor 37 and the other end of the load 40 are coupled to the ground potential GND.

In this way, the load 40, such as a headphone and a speaker, can be driven with direct current by the high side output device 31 and the low side output device 32 of the digital amplifier 30, in an OCL (Output Capacitor Less) system, via the low pass filter LPF. Therefore, it becomes possible to improve the audio reproduction property in a low frequency region of several tens or less Hz, by adoption of the OCL system, rather than the case where an output capacitor is used. The inductor 36 and the filter capacitor 37 of the low pass filter LPF of the digital amplifier 30 are implemented in the wiring substrate of the portable-use audio equipment, as an external component of the semiconductor integrated circuit 100.

An external component capacitor 60 for reducing power source noises, such as a power supply pumping, is coupled between the positive power supply voltage +Vcc and the negative power supply voltage −Vcc of the digital amplifier 30.

The Charge Pump Unit

The charge pump unit 50 operates as a positive/negative power supply voltage generator which generates the positive power supply voltage +Vcc and the negative power supply voltage −Vcc, by being supplied with a positive operating voltage Vop of a battery of a portable-use audio equipment. The charge pump unit 50 includes six switches SW1-SW6 whose switching is controlled, and four capacitors C1-C4 connected via six nodes 191-196.

First capacitor C1 is connected between a first node 191 and a second node 192. Second capacitor C2 is connected between the second node 192 and a third node 193. Third capacitor C3 is connected between a fourth node 194 and a fifth node 195. Fourth capacitor is connected between the fifth node 195 and a sixth node 196.

First switch SW1 selectively connects the positive operating voltage +Vop to the first node 191 while second switch SW2 selectively connects the ground potential GND to the third node 193. Third switch SW3 selectively connects the first node 191 and the fourth node 194. Fourth switch SW4 selectively connects the third node 193 and the sixth node 196. Fifth switch SW5 selectively connects the second node 192 and the fifth node 195. Sixth switch SW6 selectively connects the second node 192 and the fourth node 194.

The positive power supply voltage +Vcc is produced at the fourth node (194) while the negative power supply voltage −Vcc produced at the sixth node 196, with the intervening fifth node 195 being connected to the ground potential (GND).

The positive operating voltage Vop is supplied to one end of the first switch SW1, and the ground potential GND is supplied to one end of the second switch SW2. The other end of the first switch SW1 is coupled via first node 191 to one end of the first capacitor C1 and one end of the third switch SW3. The other end of the second switch SW2 is coupled via third node 193 to one end of the second capacitor C2 and one end of the fourth switch SW4.

A second node 192 is connected to other end of the first capacitor C1 and the other end of the second capacitor C2. Second node 192 is also connected to one end of the fifth switch SW5 and one end of the sixth switch SW6. Thus, intermediate second node 192 is between first node 191 and third node 193, with capacitors C1 and C2 between adjacent nodes.

A fourth node 194 is connected to the other end of the third switch SW3, the other end of the sixth switch SW6, and one end of the third capacitor C3. The positive power supply voltage +Vcc is generated at this fourth node 194,

A fifth node 195 is connected to the other end of the third capacitor C3, the other end of fifth switch SW5, and also to one end of the fourth capacitor C4. Fifth node 195 is also connected to the ground potential GND.

A sixth node 196 is connected to the other end of fourth switch SW4 and also to the other end of the fourth capacitor C4. Thus, intermediate fifth node 195 is between fourth node 194 and sixth node 196, with capacitors C3 and C4 between adjacent nodes. The negative power supply voltage −Vcc is generated at this sixth node 196.

The positive power supply voltage +Vcc generated by the charge pump unit 50 at the fourth node 194 is supplied to the digital signal processing unit 10, the electronic volume unit 20, and the digital amplifier 30. The negative power supply voltage −Vcc generated by the charge pump unit 50 at the sixth node 196 is supplied to the electronic volume unit 20 and the digital amplifier 30.

Although not restricted in particular, each of the first capacitor C1, the second capacitor C2, the third capacitor C3, and the fourth capacitor C4 is provided as an external capacitor of the semiconductor integrated circuit 100. On the other hand, each of the first switch SW1, the second switch SW2, the third switch SW3, the fourth switch SW4, the fifth switch SW5, and the sixth switch SW6 is provided as an internally configured switch of the semiconductor integrated circuit 100. When capacitors C1 to C4 are external to the semiconductor integrated circuit 100, the semiconductor integrated circuit will be configured to electrically connect the external capacitors C1 to C4 between appropriate internal nodes 191-196 by means of, e.g., pins, leads or the like.

A Charge Cycle of the Input Side Capacitor of the Charge Pump Unit

FIG. 2 explains operation of a first charging state in which the input capacitors, i.e., first capacitor C1 and the second capacitor C2 on the input side of the charge pump unit 50 undergo a charge cycle in which they are charged by the supply voltage Vop.

As illustrated in FIG. 2, in the charge cycle of the input side capacitors, in response to the charge pump driving clock signal (not shown in FIG. 2), the first switch SW1, the second switch SW2, and the sixth switch SW6 are controlled to an on state (i.e., closed), and the third switch SW3, the fourth switch SW4, and the fifth switch SW5 are controlled to an off state (i.e., open). Therefore, the first capacitor C1 and the second capacitor C2 of the input side of the charge pump unit 50 are charged with a voltage between the positive operating voltage Vop and the ground potential GND. Since the value of capacitance of the first capacitor C1 and the value of capacitance of the second capacitor C2 of an input side are set up equally, when the voltage of the positive operating voltage Vop is assumed to be 1.8V, the charge pump unit 50 operates such that a charge voltage of 0.9V is supplied between the both ends of the first capacitor C1, and that a charge voltage of 0.9V is supplied also between both ends of the second capacitor C2. Since the sixth switch SW6 is controlled to be an on state in this period, some charges of the second capacitor C2 move to the third capacitor C3.

Although not restricted in particular, for example, a driving clock of the charge pump unit 50 is set as a clock frequency of 384 kHz of fixed duty, and the PWM output signal of the digital amplifier 30 is given by a modulated carrier of a frequency of 768 kHz.

Although not restricted in particular, the charge pump driving clock signal supplied to the charge pump unit 50 may be considered as either of or both of the first driving output signal of the first output terminal 31 and the second driving output signal of the second output terminal 32, of the gate driver 33. In this case, in response to the charge pump driving clock signal, the high side output device 31 of the digital amplifier 30 is set to on in the period when the charge pump unit 50 is controlled to the charge cycle of the input side capacitor.

A Charge Cycle of the Output Side Capacitor of the Charge Pump Unit

FIG. 3 explains operation of a first discharging state in which the output capacitors, i.e., third capacitor C3 and the fourth capacitor C4 on the output side of the charge pump unit 50 undergo a charge cycle.

As illustrated in FIG. 3, in the charge cycle of the output side capacitor, in response to the charge pump driving clock signal (not shown in FIG. 2), the first switch SW1, the second switch SW2, and the sixth switch SW6 are controlled to an off state (i.e., open), and the third switch SW3, the fourth switch SW4, and the fifth switch SW5 are controlled to an on state (i.e., closed). In this state, capacitors C1 and C3 are connected in electrical parallel and capacitors C2 and C4 are connected in electrical parallel, with switch SW6 being open and intermediate second node 192 and fifth node 195 both being connected to ground potential GND.

Therefore, the charge voltage between both ends of the first capacitor C1 of the input side is supplied to both ends of the third capacitor C3 of the output side via the third switch SW3 and the fifth switch SW5. The charge voltage between both ends of the second capacitor C2 of the input side is supplied to both ends of the fourth capacitor C4 of the output side via the fourth switch SW4 and the fifth switch SW5. Since the fifth node 195 at the other end of the third capacitor C3 and the other end of the fourth capacitor C4 is coupled to the ground potential GND, the positive power supply voltage +Vcc of approximately +0.9V is generated from the fourth node 194 connected to the other end of the third switch SW3, the other end of the sixth switch SW6, and one end of the third capacitor C3. Meanwhile, the negative power supply voltage −Vcc of approximately −0.9V is generated from the sixth node 196 node connected to the other end of the fourth switch SW4, and one end of the fourth capacitor C4.

Although not restricted in particular, for example, a driving clock of the charge pump unit 50 is set as a clock frequency of 384 kHz of fixed duty, and, the PWM output signal of the digital amplifier 30 is given by a modulated carrier of a frequency of 768 kHz. Furthermore, the power source variation of the digital amplifier 30 arising from the regenerative current of the inductor 36 of the low pass filter LPF of the digital amplifier 30 is absorbed in the charge cycle of the output side capacitors C3 and C4 of the charge pump unit 50.

Although not restricted in particular, the charge pump driving clock signal supplied to the charge pump unit 50 may be considered as either of or both of the first driving output signal of the first output terminal of the gate driver 33 and the second driving output signal of the second output terminal. In this case, in response to the charge pump driving clock signal, the low side output device 32 of the digital amplifier 30 is set to an on state, in the period when the charge pump unit 50 is controlled to the charge cycle of the output side capacitor.

Operation of the Charge Pump Unit, the Digital Amplifier, and the Low Pass Filter

FIG. 4 explains operation of the charge pump unit 50, the digital amplifier 30, and the low pass filter LPF, included in the semiconductor integrated circuit 100 with the built-in digital amplifier according to Embodiment 1 of the present invention, illustrated in FIG. 1.

FIG. 4 also illustrates the manner in which, when the charge pump unit 50 is in a first charging state, during the charge cycle of the input side capacitor of the charge pump unit 50, a variation of the positive power supply voltage arising from the regenerative current, which flows from the one end of the filter capacitor 37 of the low pass filter LPF and the one end of the speaker load 40, through the inductor 36 and the high side output device 31, to the positive power supply voltage +Vcc, is absorbed by the charge pump unit 50. This can be considered an input charging/regeneration state, since the regeneration occurs while input capacitors C1 and C2 are being charged by the operating voltage Vop. Before explaining FIG. 4, the following explains why the regenerative current flows.

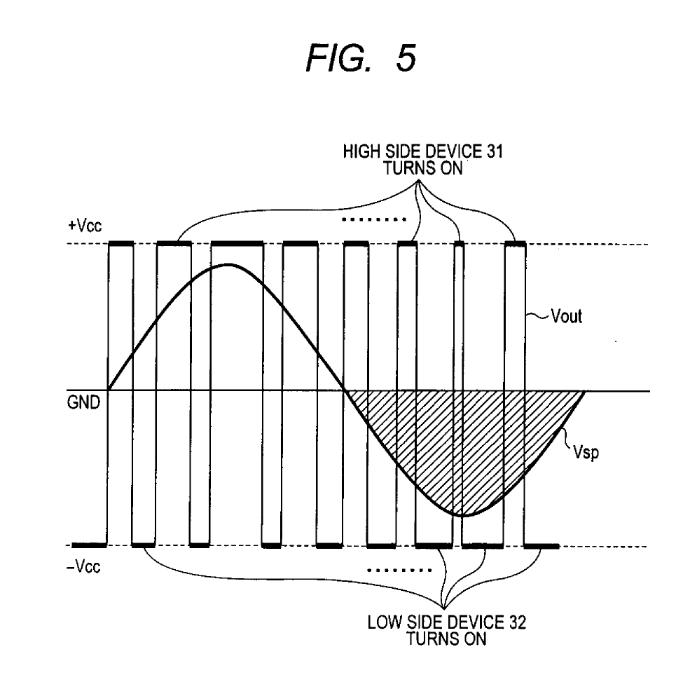

FIG. 5 illustrates a waveform of a PWM digital audio amplified output signal Vout in the output terminal 300 of the digital amplifier 30 and a waveform of an analog audio amplified output signal Vsp in the output terminal of the low pass filter LPF. Here, the output terminal of the digital amplifier 30 is the common drain node 300 of a drain terminal of the high side output device 31 and a drain terminal of the low side output device 32 of the digital amplifier 30 included in the semiconductor integrated circuit 100 with the built-in digital amplifier according to Embodiment 1 of the present invention, illustrated in FIG. 1.

As illustrated in FIG. 5, in the period when the high side output device 31 is in an on state, the PWM digital audio amplified output signal Vout is set at a voltage level of the positive power supply voltage +Vcc of a high level, and in the period when the low side output device 32 is in an on state, the PWM digital audio amplified output signal Vout is set at a voltage level of the negative power supply voltage −Vcc of a low level.

Furthermore, as illustrated in FIG. 5, when the period of the on state of the high side output device 31 is longer than the period of the on state of the low side output device 32, the voltage level of the analog audio amplified output signal Vsp at the output terminal of the low pass filter LPF is set at a voltage level close to the positive power supply voltage +Vcc of a high level. On the contrary, when the period of the on state of the high side output device 31 is shorter than the period of the on state of the low side output device 32, the voltage level of the analog audio amplified output signal Vsp in the output terminal of the low pass filter LPF is set at a voltage level close to the negative power supply voltage −Vcc of a low level.

Therefore, as illustrated in FIG. 5, when the period of the on state of the high side output device 31 is shorter than the period of the on state of the low side output device 32, the voltage level of the analog audio amplified output signal Vsp becomes a negative voltage lower than the ground voltage GND.

The low side output device 32 is set in an on state for a long time in the period when the voltage level of the analog audio amplified output signal Vsp is at a negative voltage lower than the ground voltage GND. Accordingly, in the period when the low side output device 32 is set in an on state, energization current flows, as indicated by a solid line L1 in FIG. 4, from the one end of the filter capacitor 37 of the low pass filter LPF and the one end of the speaker load 40, through the inductor 36 and the low side output device 32 set in an on state, toward the negative power supply voltage −Vcc. However, even in the period when the voltage level of the analog audio amplified output signal Vsp is a negative voltage lower than the ground voltage GND, the high side output device 31 is set in an on state for a short time. Therefore, in the short “on” period of the high side output device 31, as indicated by a dashed line L2 in FIG. 4, regenerative current of the same current value and the same direction as the above-mentioned energization current flows from the one end of the filter capacitor 37 of the low pass filter LPF and the one end of the speaker load 40, through the inductor 36 and the high side output device 31 in an on state, toward the positive power supply voltage +Vcc. Consequently, the positive power supply voltage +Vcc is varied by the inflow of the regenerative current to the positive power supply voltage +Vcc. It is conjectured that this is an occurrence mechanism of the power supply pumping arising from the inflow of the energy stored in the inductor 36 of the output LPF of the digital amplifier 30 to the power supply.

However, according to the semiconductor integrated circuit 100, the charge pump unit 50 is controlled during the charge cycle of the input side capacitor, in response to the charge pump driving clock signal, as illustrated in FIG. 4. That is, the first switch SW1, the second switch SW2, and the sixth switch SW6 are controlled to an on state (are closed), and the third switch SW3, the fourth switch SW4, and the fifth switch SW5 are controlled to an off state (are open). Therefore, as illustrated in FIG. 4, it is possible to suppress a variation of the positive power supply voltage +Vcc, because the regenerative current flows into the second capacitor C2 of the input side of the charge pump unit 50 via the sixth switch SW6 set in an on state. In this period, the first capacitor C1 and the second capacitor C2 of the input side of the charge pump unit 50 are charged by a voltage between the positive operating voltage Vop and the ground potential GND, as indicated by a solid line L0 in FIG. 4. However, since the regenerative current flows into the first capacitor C1 and the second capacitor C2 at this time, it is possible to reduce the consumption of a battery, which is employed in a portable-use audio equipment for supplying the positive operating voltage Vop to charge the first capacitor C1 and the second capacitor C2 of the input side of the charge pump unit 50.

Although not restricted in particular, the inductor 36 and the filter capacitor 37 configuring the low pass filter LPF are provided as external components coupled outside the semiconductor integrated circuit 100.

As explained in the above, by using the semiconductor integrated circuit 100, it is possible to suppress the variation of the positive power supply voltage +Vcc arising from the regenerative current of the inductor 36 of the low pass filter LPF. It is also possible to suppress a variation of the negative power supply voltage −Vcc which arises, from the same mechanism, when the voltage level of the analog audio amplified output signal Vsp becomes a positive voltage higher than the ground voltage GND, as will be described in the following. Consequently, the value of capacitance of the external component capacitor 60, which is coupled between the positive power supply voltage +Vcc and the negative power supply voltage −Vcc of the digital amplifier 30 for reducing power source noises such as power supply pumping, can be made as small as 10 μF, which is much reduced from the conventional large mass capacitor of 470 μF. Accordingly, it has become possible to reduce the cost and the mounting area of a wiring substrate of a portable-use audio equipment.

Other Operation of the Charge Pump Unit, the Digital Amplifier, and the Low Pass Filter

Next, the following considers the case where the operating frequency of the charge pump unit differs from the operating frequency of the digital amplifier, and the state where the low level period of the duty of the output of the digital amplifier 30 is longer than the high level period continues for a long period of time.

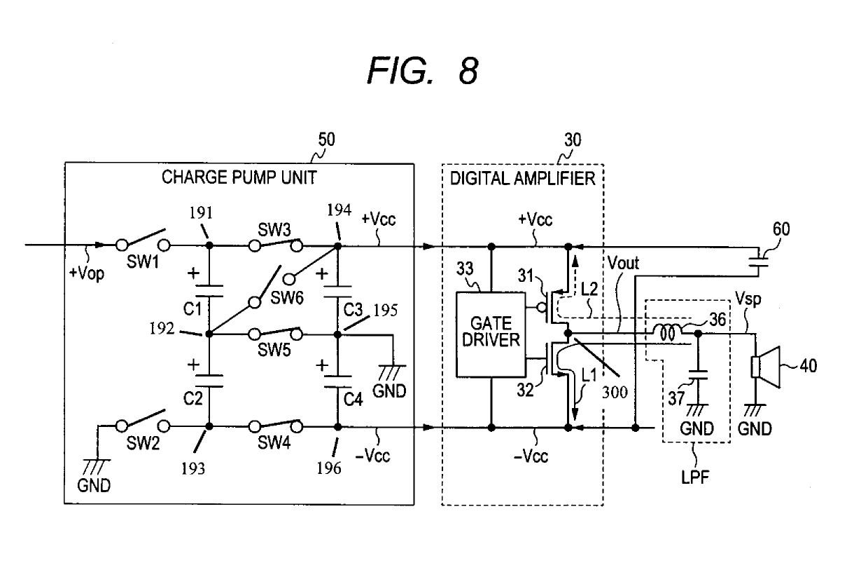

FIG. 8 explains operation of the charge pump unit 50, the digital amplifier 30, and the low pass filter LPF, included in the semiconductor integrated circuit 100 in the state where a low level period of the duty of the output of the digital amplifier 30 is longer than a high level period continues for a long period of time. This is the amplifier low level dominant state which has two charging sub-states, a high-side regeneration charging sub-state and a high-side regenerating transfer sub-state.

In this case, a solid line L1 in FIG. 8 indicates load current and a dashed line L2 indicates regenerative current, and the regenerative current flows like the dashed line L2 also when the charge pump unit 50 is at a discharging state.

In the high-side regeneration charging sub-state (whose switch configuration is identical to that of the first discharging state of FIG. 3), switch SW6 open. With switch SW6 open, the charge by the regenerative current is stored in the parallely connected high side capacitors, i.e., the first capacitor C1 and the third capacitor C3.

Once switch SW6 is controlled to an on state (i.e., is closed), the charge pump unit 50 enters the high-side regeneration transfer sub-state in which the charge stored in the third capacitor C3 is supplied to the second capacitor C2. Therefore, it is possible to suppress the variation of the positive power supply voltage +Vcc, and it becomes possible to reduce the consumption of a battery employed in a portable-use audio equipment, for supplying the positive operating voltage Vop.

Next, the following considers the case where the operating frequency of the charge pump unit differs from the operating frequency of the digital amplifier, and the state where the high level period of the duty of the output of the digital amplifier is longer than the low level period continues for a long period of time.

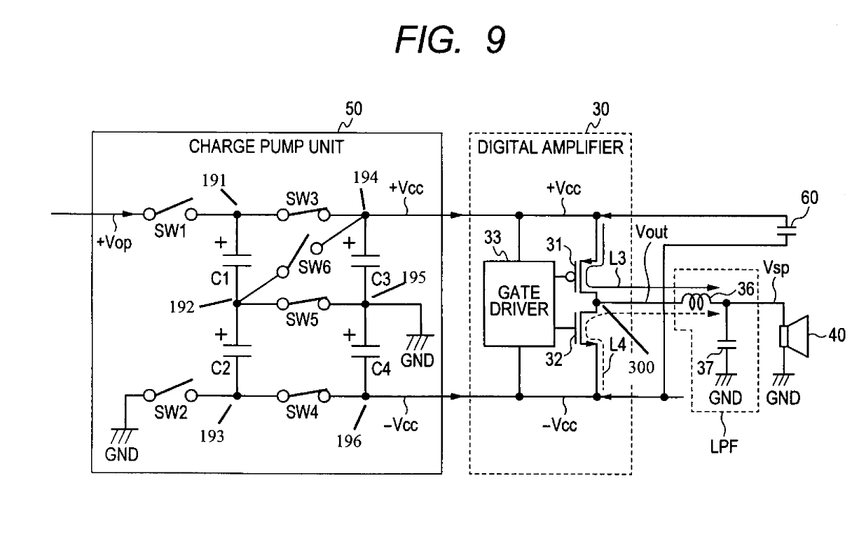

FIG. 9 explains operation of the charge pump unit 50, the digital amplifier 30, and the low pass filter LPF, included in the semiconductor integrated circuit 100 in the state where a high level period of the duty of the output of the digital amplifier 30 is longer than a low level period continues for a long period of time. This is the amplifier high level dominant state which has two charging sub-states, a low-side regeneration charging sub-state and a low-side regeneration transfer sub-state.

In this case, a solid line L3 in FIG. 9 indicates load current, a dashed line L4 indicates regenerative current which is supplied from the negative supply voltage −Vcc, and the regenerative current flows like the dashed line L4 also when the charge pump unit is in a discharging state.

In the low-side regeneration charging sub-state (whose switch configuration is identical to that of the first discharging state of FIG. 3), switch SW6 is again open. With switch SW6 open, the charge by the regenerative current is stored in the parallely connected low side capacitors, i.e., the second capacitor C2 and the fourth capacitor C4.

Once switch SW6 is controlled to an on state (i.e., is closed), the charge pump unit 50 enters the low-side regeneration transfer sub-state in which the charge stored in the second capacitor C2 is supplied to the third capacitor C3. Therefore, it is possible to suppress the variation of the negative power supply voltage −Vcc, and it becomes possible to reduce the consumption of a battery employed in a portable-use audio equipment, for supplying the positive operating voltage Vop.

In the case where, due to the operation described above, the operating frequency of the charge pump unit 50 and the operating frequency of the digital amplifier 30 are different and an audio signal has an arbitrary frequency, it becomes possible to reduce the regenerative current-attributable pumping of either the positive power supply voltage +Vcc or the negative power supply voltage −Vcc.

Operation of the Electronic Volume Unit

FIG. 6 illustrates the state of analog amplitude control of a PWM digital audio signal B by the PWM amplitude control electronic volume 22, and the state of amplitude control of a PWM digital audio amplified signal E by the digital amplifier gain control circuit 23, provided in the electronic volume unit 20 included in the semiconductor integrated circuit 100.

As illustrated in FIG. 6, the electronic volume unit 20 includes the volume control signal generating circuit 21, the PWM amplitude control electronic volume 22, the digital amplifier gain control circuit 23, and the level shift circuit 24.

The volume control signal generating circuit 21 generates the PWM amplitude control digital signal C to be supplied to the PWM amplitude control electronic volume 22 and the gain control digital signal F to be supplied to the digital amplifier gain control circuit 23, in response to the digital control signal D1 supplied from the digital interface unit 15.

The PWM amplitude control electronic volume 22, operating with the positive power supply voltage +Vcc and the negative power supply voltage −Vcc, generated by the charge pump unit 50, controls the analog amplitude of the PWM digital audio signal B supplied from the ΔΣ modulator-PWM generator unit 14 via the level shift circuit 24, in response to the PWM amplitude control digital signal C supplied from the volume control signal generating circuit 21. Therefore, as illustrated in FIG. 6, it is possible to adjust the analog amplitude of the PWM digital audio output signal D2 obtained from the output terminal of the PWM amplitude control electronic volume 22, between the negative power supply voltage −Vcc and the positive power supply voltage +Vcc.

On the other hand, the digital amplifier gain control circuit 23 includes the variable attenuator 232 in order to process the PWM digital audio output signal D2 supplied from the PWM amplitude control electronic volume 22. The variable attenuator 232 includes plural resistors R₁, R₂, - - - , R_{N-1}, and R_{N} coupled in series and plural bypass switches SW₁, SW₂, - - - , SW_{N-1}, and SW_{N} coupled in series, each switch permitting bypass of a corresponding resistor. The on/off state of each of the plural bypass switches SW₁, SW₂, - - - , SW_{N-1}, and SW_{N} of the variable attenuator 232 is controlled by the gain control digital signal F supplied from the volume control signal generating circuit 21.

For example, when all plural bypass switches SW₁, SW₂, - - - , SW_{N-1}, and SW_{N} of the variable attenuator 232 are controlled to an off state, the value of resistance of the variable attenuator 232 is maximized (since none of the resistors are bypassed), and the voltage amplitude of the PWM digital audio amplified signal E of the digital amplifier 30 applied to the inverting input terminal (−) (49) of the differential amplifier 34, and connected to the driver output 300 via the negative feedback resistor R_{FB}, is at a maximum.

As described above, the timing of controlling the analog amplitude of the PWM digital audio signal B by the PWM amplitude control electronic volume 22 in response to the PWM amplitude control digital signal C precedes in time the timing of controlling the voltage amplitude of the PWM digital audio amplified signal E by the digital amplifier gain control circuit 23 in response to the gain control digital signal F. Consequently, it becomes possible to reduce the pop noise (popping sound) arising from the rapid change of the audio signal due to the change of the digital control signal for the volume adjustment.

FIG. 7 illustrates a manner in which popping sound is reduced by use of the electronic volume unit 20 of the semiconductor integrated circuit 100.

The upper part of FIG. 7 illustrates the waveform of the PWM digital audio signal B generated by the ΔΣ modulator-PWM generator unit 14 of the digital signal processing unit 10 before and after the gain is changed.

The middle part of FIG. 7 illustrates the waveform of the PWM digital audio amplified signal E of the digital amplifier 30, in the case of using only the digital amplifier gain control circuit 23, without using the PWM amplitude control electronic volume 22 in the electronic volume unit 20 illustrated in FIG. 1.

The lower part of FIG. 7 illustrates the waveform of the PWM digital audio amplified signal E of the digital amplifier 30, when both the PWM amplitude control electronic volume 22 and the digital amplifier gain control circuit 23 in the electronic volume unit 20 are used, and when the timing of controlling the analog amplitude by the PWM amplitude control electronic volume 22 in response to the PWM amplitude control digital signal C precedes in time the timing of controlling the voltage amplitude by the digital amplifier gain control circuit 23 in response to the gain control digital signal F.

In the case of the middle waveform (1) in FIG. 7, there is no change of the electronic volume performed in response to the PWM amplitude control digital signal C, which precedes in time the gain change performed in response to the gain control digital signal F. Therefore, a popping sound is generated due to a rapid change of amplitude S3 in the PWM digital audio amplified signal E, performed in response to the change of the gain control digital signal F.

On the contrary, in the case of the lower waveform (2) in FIG. 7 which employs the electronic volume unit 20 of the semiconductor integrated circuit 100 with the built-in digital amplifier according to Embodiment 1 of the present invention illustrated in FIG. 1, there is reduction of the amplitude due to the change of the electronic volume performed in response to the PWM amplitude control digital signal C, which precedes the gain change performed in response to the gain control digital signal F. Therefore, it is possible to reduce the popping sound arising from a rapid change of reduced amplitude S4 in the PWM digital audio amplified signal E, due to the change of the gain control digital signal F.

As described above, the invention accomplished by the present inventors has been concretely explained based on various embodiments. However, it cannot be overemphasized that the present invention is not restricted to the embodiments, and it can be changed variously in the range which does not deviate from the gist.

For example, instead of coupling as a single external component the capacitor 60 for reducing power source noises, such as power supply pumping, between the positive power supply voltage +Vcc and the negative power supply voltage −Vcc of the digital amplifier 30, it is also possible to couple a first capacitor between the positive power supply voltage +Vcc and the ground potential GND, and to couple a second capacitor between the ground potential GND and the negative power supply voltage −Vcc.

Furthermore, the ΔΣ modulator-PWM generator unit 14 of the digital signal processing unit 10 illustrated in FIG. 1 may be replaced by a ΔΣ modulator and a PDM generator, and the PWM amplitude control electronic volume 22 of the electronic volume unit 20 may be replaced by a PDM amplitude control electronic volume.

Furthermore, the high side output device 31 and the low side output device 32 of the digital amplifier 30 are not restricted to the P-channel MOS transistor and the N-channel MOS transistor, respectively. For instance, they may be replaced by a PNP bipolar transistor and an NPN bipolar transistor.

Moreover, the inductor 36 and the filter capacitor 37 of the low pass filter LPF for suppressing the PWM carrier frequency of a high frequency at the output of the digital amplifier 30 may be formed as a system in package (SIP) built in a resin sealed package containing the semiconductor chip of the semiconductor integrated circuit 100.

What is claimed is:

1. A semiconductor integrated circuit comprising:
a digital amplifier including a high side output device, a low side output device, and a driver; and
a charge pump unit supplied with a positive operating voltage and configured to generate a positive power supply voltage and a negative power supply voltage in response thereto,
wherein the driver of the digital amplifier operates with the positive power supply voltage and the negative power supply voltage, and a first output terminal and a second output terminal of the driver are coupled to a control input terminal of the high side output device and a control input terminal of the low side output device, respectively,
wherein an output current path of the high side output device is coupled between the positive power supply voltage and an output terminal of the digital amplifier, and an output current path of the low side output device is coupled between the output terminal of the digital amplifier and the negative power supply voltage,
wherein the output terminal of the digital amplifier is coupled to a low pass filter including an inductor and a filter capacitor,
wherein the charge pump unit comprises a first switch through a fifth switch, and a first capacitor through a fourth capacitor, all connected via a first node through a sixth node,
wherein the positive operating voltage is supplied to one end of the first capacitor via the first switch, a ground potential is supplied to one end of the second capacitor via the second switch, and the other end of the first capacitor and the other end of the second capacitor are coupled to a second node,
wherein the one end of the first capacitor is coupled to one end of the third capacitor via the third switch, the one end of the second capacitor is coupled to one end of the fourth capacitor via the fourth switch, a second node is connected to the other end of the third capacitor and the other end of the fourth capacitor and is coupled to the ground potential, and the second node is coupled to the fifth node via the fifth switch,
wherein the positive power supply voltage is generated from the one end of the third capacitor, and the negative power supply voltage is generated from the one end of the fourth capacitor,
wherein the charge pump unit further comprises a sixth switch coupled between the one end of the third capacitor and the second node, and
wherein the regenerative current which flows between the capacitor of the low pass filter and the positive power supply voltage or the negative power supply voltage, via the inductor and the high side output device or the low side output device in an on state, is absorbed by the second capacitor, by controlling the sixth switch of the charge pump unit to an on state.

2. The semiconductor integrated circuit according to claim 1,
wherein, in response to a level change of a charge pump driving clock signal, the charge pump unit repeats operation of a charge cycle of an input side capacitor and operation of a charge cycle of an output side capacitor,
wherein, in the charge cycle of the input side capacitor, the positive operating voltage is supplied to the one end of the first capacitor and the ground potential is supplied to the one end of the second capacitor, by controlling the first switch, the second switch, and the sixth switch to an on state, and controlling the third switch, the fourth switch, and the fifth switch to an off state, and
wherein, in the charge cycle of the output side capacitor, the positive power supply voltage is generated from the one end of the third capacitor and the negative power supply voltage is generated from the one end of the fourth capacitor, by controlling the first switch, the second switch, and the sixth switch to an off state, and controlling the third switch, the fourth switch, and the fifth switch to an on state.

3. The semiconductor integrated circuit according to claim 2,
wherein, in a charge cycle of the input side capacitor, the high side output device and the low side output device of the digital amplifier are controlled to an on state and an off state, respectively, by the first driving signal of the first output terminal of the driver and the second driving signal of the second output terminal, and
wherein, in a charge cycle of the output side capacitor, the high side output device and the low side output device of the digital amplifier are controlled to an off state and an on state, respectively, by the first driving signal of the first output terminal of the driver and the second driving signal of the second output terminal.

4. The semiconductor integrated circuit according to claim 2,
wherein the digital amplifier further comprises a differential amplifier, a closed-loop characteristics setting circuit, and a negative feedback resistor, and
wherein a noninverting input terminal of the differential amplifier is coupled to the ground potential, the closed-loop characteristics setting circuit is coupled between an inverting input terminal and an output terminal of the differential amplifier, the output terminal of the differential amplifier is coupled to an input terminal of the driver, and the negative feedback resistor is coupled between the inverting input terminal of the differential amplifier and the output terminal of the digital amplifier.

5. The semiconductor integrated circuit according to claim 4, further comprising:
an electronic volume unit including a volume control signal generating circuit, an amplitude control electronic volume, and a digital amplifier gain control circuit,
wherein, in response to a digital control signal, the volume control signal generating circuit generates an amplitude control digital signal to be supplied to the amplitude control electronic volume, and a gain control digital signal to be supplied to the digital amplifier gain control circuit,
wherein the amplitude control electronic volume, operating with the positive power supply voltage and the negative power supply voltage, controls analog amplitude of a digital audio output signal supplied from an output of the amplitude control electronic volume to an input of the digital amplifier gain control circuit in response to the amplitude control digital signal, and
wherein the digital amplifier gain control circuit controls amplitude of a digital audio amplified output signal of the output terminal of the digital amplifier by controlling the voltage gain of the digital amplifier in response to the gain control digital signal.

6. The semiconductor integrated circuit according to claim 5,
wherein the timing of controlling the analog amplitude of the digital audio output signal by the amplitude control electronic volume in response to the amplitude control digital signal precedes in time the timing of controlling the digital audio amplified output signal by the digital amplifier gain control circuit in response to the gain control digital signal.

7. The semiconductor integrated circuit according to claim 6,
wherein the timing of supplying the amplitude control digital signal from the volume control signal generating circuit to the amplitude control electronic volume is advanced, on the other hand, the timing of supplying the gain control digital signal from the volume control signal generating circuit to the digital amplifier gain control circuit is delayed.

8. The semiconductor integrated circuit according to claim 7,
wherein the digital amplifier gain control circuit comprises a variable attenuator including a plurality of resistors coupled in series and a plurality of bypass switches coupled in series, in order to control the voltage gain of the digital amplifier in response to the gain control digital signal, and
wherein the on/off state of the plural bypass switches of the variable attenuator is controlled by the gain control digital signal supplied from the volume control signal generating circuit.

9. The semiconductor integrated circuit according to claim 8, further comprising:
an audio signal processing circuit with a built-in digital electronic volume;
a ΔΣ modulator-PWM/PDM generator unit; and
a digital signal processing unit including a digital interface unit,
wherein the digital interface unit of the digital signal processing unit is operable to generate the digital control signal to be supplied to the volume control signal generating circuit of the electronic volume unit,
wherein the digital electronic volume of the audio signal processing circuit is operable to control a digital amplitude value of a digital audio signal, in response to a digital volume control signal supplied from the digital interface unit, and
wherein the ΔΣ modulator-PWM/PDM generator unit is operable to generate a PWM/PDM digital audio signal in response to the digital audio signal supplied from an output terminal of the audio signal processing circuit.

10. The semiconductor integrated circuit according to claim 1,
wherein the high side output device and the low side output device included in the digital amplifier are MOS transistors integrated in the semiconductor integrated circuit.

11. An operating method of a semiconductor integrated circuit,
wherein the semiconductor integrated circuit comprises:
a digital amplifier including a high side output device, a low side output device, and a driver; and
a charge pump unit supplied with a positive operating voltage and configured to generate a positive power supply voltage and a negative power supply voltage in response thereto,
wherein the driver of the digital amplifier operates with the positive power supply voltage and the negative power supply voltage, and a first output terminal and a second output terminal of the driver are coupled to a control input terminal of the high side output device and a control input terminal of the low side output device, respectively,
wherein an output current path of the high side output device is coupled between the positive power supply voltage and an output terminal of the digital amplifier, and an output current path of the low side output device is coupled between the output terminal of the digital amplifier and the negative power supply voltage,
wherein the output terminal of the digital amplifier is coupled to a low pass filter including an inductor and a filter capacitor,
wherein the charge pump unit comprises a first switch through a fifth switch, and a first capacitor through a fourth capacitor, all connected via a first node through a sixth node,
wherein the positive operating voltage is supplied to one end of the first capacitor via the first switch, a ground potential is supplied to one end of the second capacitor via the second switch, and the other end of the first capacitor and the other end of the second capacitor are coupled to a second node,
wherein the one end of the first capacitor is coupled to one end of the third capacitor via the third switch, the one end of the second capacitor is coupled to one end of the fourth capacitor via the fourth switch, a fifth node is connected to the other end of the third capacitor and the other end of the fourth capacitor and is coupled to the ground potential, and the second node is coupled to the fifth node via the fifth switch,
wherein the positive power supply voltage is generated from the one end of the third capacitor, and the negative power supply voltage is generated from the one end of the fourth capacitor, and
wherein the charge pump unit further comprises a sixth switch coupled between the one end of the third capacitor and the second node,
the method comprising:
controlling the sixth switch of the charge pump unit to an on state to thereby cause the second capacitor to absorb regenerative current which flows between the filter capacitor of the low pass filter and the positive power supply voltage or the negative power supply voltage, via the inductor and the high side output device or the low side output device.

12. The operating method of the semiconductor integrated circuit according to claim 11, comprising:
in response to a level change of a charge pump driving clock signal, repeating, by the charge pump unit, operation of a charge cycle of an input side capacitor and operation of a charge cycle of an output side capacitor,
in the charge cycle of the input side capacitor, controlling the first switch, the second switch, and the sixth switch to an on state, and controlling the third switch, the fourth switch, and the fifth switch to an off state, so that the positive operating voltage is supplied to the one end of the first capacitor and the ground potential is supplied to the one end of the second capacitor, and
in the charge cycle of the output side capacitor, controlling the first switch, the second switch, and the sixth switch to an off state, and controlling the third switch, the fourth switch, and the fifth switch to an on state, so that the positive power supply voltage is generated from the one end of the third capacitor and the negative power supply voltage is generated from the one end of the fourth capacitor.

13. The operating method of the semiconductor integrated circuit according to claim 12, comprising:
in a charge cycle of the input side capacitor, controlling the high side output device and the low side output device of the digital amplifier to an on state and an off state, respectively, by the first driving signal of the first output terminal of the driver and the second driving signal of the second output terminal, and
in a charge cycle of the output side capacitor, controlling the high side output device and the low side output device of the digital amplifier to an off state and an on state, respectively, by the first driving signal of the first output terminal of the driver and the second driving signal of the second output terminal.

14. The operating method of the semiconductor integrated circuit according to claim 12,
wherein the digital amplifier further comprises a differential amplifier, a closed-loop characteristics setting circuit, and a negative feedback resistor,
wherein a noninverting input terminal of the differential amplifier is coupled to the ground potential, the closed-loop characteristics setting circuit is coupled between an inverting input terminal and an output terminal of the differential amplifier, the output terminal of the differential amplifier is coupled to an input terminal of the driver,
the method further comprising:
providing negative feedback from the output terminal of the differential amplifier to the inverting input terminal of the differential amplifier.

15. The operating method of the semiconductor integrated circuit according to claim 14,
wherein the semiconductor integrated circuit further comprises an electronic volume unit including a volume control signal generating circuit, an amplitude control electronic volume, and a digital amplifier gain control circuit,
the method further comprising:
in response to a digital control signal, generating, by the volume control signal generating circuit, an amplitude control digital signal to be supplied to the amplitude control electronic volume, and a gain control digital signal to be supplied to the digital amplifier gain control circuit,
in response to the amplitude control digital signal, controlling, by the amplitude control electronic volume operating with the positive power supply voltage and the negative power supply voltage, analog amplitude of a digital audio output signal supplied from an output of the amplitude control electronic volume to an input of the digital amplifier gain control circuit, and
in response to the gain control digital signal, controlling, by the digital amplifier gain control circuit, amplitude of a digital audio amplified output signal of the output terminal of the digital amplifier by controlling the voltage gain of the digital amplifier.

16. The operating method of the semiconductor integrated circuit according to claim 15, comprising:
controlling the analog amplitude of the digital audio output signal by the amplitude control electronic volume in response to the amplitude control digital signal prior to controlling the digital audio amplified output signal by the digital amplifier gain control circuit in response to the gain control digital signal.

17. The operating method of the semiconductor integrated circuit according to claim 16, comprising:
advancing the timing of supplying the amplitude control digital signal from the volume control signal generating circuit to the amplitude control electronic volume; and
delaying the timing of supplying the gain control digital signal from the volume control signal generating circuit to the digital amplifier gain control circuit.

18. The operating method of the semiconductor integrated circuit according to claim 17,
wherein the digital amplifier gain control circuit comprises a variable attenuator including a plurality of resistors coupled in series and a plurality of bypass switches coupled in series, in order to control the voltage gain of the digital amplifier in response to the gain control digital signal,
the method further comprising:
controlling the on/off state of the plurality of bypass switches of the variable attenuator with the gain control digital signal supplied from the volume control signal generating circuit.

19. The operating method of the semiconductor integrated circuit according to claim 18,
wherein the semiconductor integrated circuit further comprises:
an audio signal processing circuit with a built-in digital electronic volume;
a ΔΣ modulator-PWM/PDM generator unit; and
a digital signal processing unit including a digital interface unit, and
the method further comprises:
generating, by the digital interface unit of the digital signal processing unit, the digital control signal to be supplied to the volume control signal generating circuit of the electronic volume unit,
controlling, by the digital electronic volume of the audio signal processing circuit, a digital amplitude value of a digital audio signal, in response to a digital volume control signal supplied from the digital interface unit, and
generating, by the ΔΣ modulator-PWM/PDM generator unit, a PWM/PDM digital audio signal in response to the digital audio signal supplied from an output terminal of the audio signal processing circuit.

20. The operating method of the semiconductor integrated circuit according claim 11,
wherein the high side output device and the low side output device included in the digital amplifier are MOS transistors integrated in the semiconductor integrated circuit.

21. A semiconductor integrated circuit comprising:
a digital amplifier including a high side output device, a low side output device, and a driver; and
a charge pump unit operable to generate a positive power supply voltage and a negative power supply voltage to be supplied to the digital amplifier, by being supplied with a positive operating voltage,
wherein the driver of the digital amplifier operates with the positive power supply voltage and the negative power supply voltage, and a first output terminal and a second output terminal of the driver are coupled to a control input terminal of the high side output device and a control input terminal of the low side output device, respectively,
wherein an output current path of the high side output device is coupled between the positive power supply voltage and an output terminal of the digital amplifier, and an output current path of the low side output device is coupled between the output terminal of the digital amplifier and the negative power supply voltage,
wherein the output terminal of the digital amplifier is coupled to a low pass filter including an inductor and a filter capacitor,
wherein the charge pump unit comprises a first switch through a fifth switch, and a first capacitor through a fourth capacitor, all connected via a first node through a sixth node,
wherein the positive operating voltage is supplied to one end of the first capacitor via the first switch, a ground potential is supplied to one end of the second capacitor via the second switch, and the other end of the first capacitor and the other end of the second capacitor are coupled to a second node,
wherein the one end of the first capacitor is coupled to one end of the third capacitor via the third switch, the one end of the second capacitor is coupled to one end of the fourth capacitor via the fourth switch, a fifth node is connected to the other end of the third capacitor and the other end of the fourth capacitor and is coupled to the ground potential, and the second node is coupled to the fifth node via the fifth switch,
wherein the positive power supply voltage is generated from the one end of the third capacitor, and the negative power supply voltage is generated from the one end of the fourth capacitor, and
wherein the charge pump unit further comprises a sixth switch coupled between the one end of the third capacitor and the second node.

22. A semiconductor integrated circuit comprising:
a digital signal processing unit configured to output digital audio signal (B) and a digital control signal (D1);
an electronic volume control unit configured to receive, as input, the digital audio signal (B) and the digital control signal (D1), and output a digital audio amplified signal (E) in response thereto;
a digital amplifier configured to receive the digital audio amplified signal (E) and output a digital audio amplified output signal suitable for filtering and driving a speaker in response thereto; and a
a charge pump unit supplied with a positive operating voltage (+Vop) and a ground potential (GND) and configured to generate a positive power supply voltage (+Vcc) and a negative power supply voltage (−Vcc);
wherein:
the charge pump unit comprises a first switch through a fifth switch and a first node through a sixth node;
first switch (SW1) selectively connects the positive operating voltage (+Vop) to the first node (191);
second switch (SW2) selectively connects the ground potential (GND) to the third node (193);
third switch (SW3) selectively connects the first node (191) and the fourth node (194);
fourth switch (SW4) selectively connects the third node (193) and the sixth node (196);
fifth switch (SW5) selectively connects the second node (192) and the fifth node (195);
sixth switch (SW6) selectively connects the second node (192) and the fourth node (194);
the positive power supply voltage (+Vcc) is created at the fourth node (194);
the negative power supply voltage (−Vcc) is created at the sixth node (196).

23. The semiconductor integrated circuit according to claim 22, configured to:
electrically connect to a first external capacitor between the first node (191) and the second node (192);
electrically connect to a second external capacitor between the second node (192) and the third node (193);
electrically connect to a third external capacitor between the fourth node (194) and the fifth node (195); and
electrically connect to a fourth external capacitor between the fifth node (195) and the sixth node (196).

24. The semiconductor integrated circuit according to claim 22, electrically connected to:
a first external capacitor between the first node (191) and the second node (192);
a second external capacitor between the second node (192) and the third node (193);
a third external capacitor between the fourth node (194) and the fifth node (195); and
a fourth external capacitor between the fifth node (195) and the sixth node (196).

25. The semiconductor integrated circuit according to claim 24, wherein:
when the first, second and sixth switches are open and the third, fourth and fifth switches are closed, charge from a first regenerative current passing through the digital amplifier is stored in the first and third external capacitors; and
when the sixth switch is then closed, charge in the third external capacitor is supplied to the second external capacitor.

26. The semiconductor integrated circuit according to claim 24, wherein:
when the first, second and sixth switches are open and the third, fourth and fifth switches are closed, charge from a second regenerative current passing through the digital amplifier is stored in the second and fourth external capacitors; and
when the sixth switch is then closed, charge in the second external capacitor is supplied to the third external capacitor.

27. A semiconductor integrated circuit charge pump unit supplied with a positive operating voltage (+Vop) and a ground potential (GND) and configured to generate a positive power supply voltage (+Vcc) and a negative power supply voltage (−Vcc) in response thereto, wherein:
the charge pump unit comprises first through fifth switches (SW1-SW4) and first through sixth nodes (191-196);
the first switch (SW1) selectively connects the positive operating voltage (+Vop) to the first node (191);
the second switch (SW2) selectively connects a ground potential (GND) to the third node (193);
the third switch (SW3) selectively connects the first node (191) and the fourth node (194);
the fourth switch (SW4) selectively connects the third node (193) and the sixth node (196);
fifth switch (SW5) selectively connects the second node (192) and the fifth node (195);
sixth switch (SW6) selectively connects the second node (192) and the fourth node (194);
the positive power supply voltage (+Vcc) is formed at the fourth node (194);
the negative power supply voltage (−Vcc) is formed at the sixth node (196); and
the fifth node (195) is connected to the ground potential (GND).

28. A semiconductor integrated circuit electronic volume control unit (20) configured to receive a digital audio signal (B) and a digital control signal (D1), and output a digital audio amplified signal (E) in response thereto, the electronic volume control unit comprising:
a volume control signal generating circuit (21) configured to receive the digital control signal (D1) and, in response thereto, output an amplitude control digital signal (C) and a gain control digital signal (F);
an amplitude control electronic volume unit (22) configured to receive the digital audio signal (B) and, in response to the amplitude control digital signal (C), output a digital audio output signal (D2); and
a digital amplifier gain control circuit (23) configured to receive the digital audio output signal (D2) and output said digital audio amplified signal (E) in response thereto;
wherein:
the digital amplifier gain control circuit (23) comprises a variable attenuator (232) having a plurality of resistors coupled in series and a plurality of bypass switches coupled in series, each bypass switch connected in parallel across a corresponding resistor; and
an on/off state of each of the plurality of bypass switches is controlled by the gain control digital signal (F) supplied from the volume control signal generating circuit (21).
